(19) United States
(12) Patent Application Publication
(10) Pub. No.: US 2026/0135068 A1
(43) Pub. Date: May 14, 2026

(54) System and Method for Atomic Layer Etching Process for High-Aspect-Ratio Structures with Accelerated In Situ Liner Deposition

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/945,487

(22) Filed: Nov. 12, 2024

(51) Int. Cl. H01J 37/32; H01L 21/02; H01L 21/311

(52) U.S. Cl. CPC H01J 37/32449; H10P 14/6336; H10P 14/6339; H10P 50/283; H01J 2237/334

(57) ABSTRACT

Disclosed is a method and system for atomic layer etching (ALE) to enhance high aspect ratio (HAR) structure formation. The system includes a pressurized precursor buffer positioned proximate to a gas/precursor delivery unit. An in situ liner deposition step is interleaved at predetermined intervals within the ALE process cycles. A system controller monitors real-time precursor pressure within the buffer to determine and release a controlled volume of precursor into the chamber. This rapid in situ liner deposition, based on the precise volume of precursor introduced, facilitates enhanced profile control during HAR etching.

### FIELD OF THE INVENTION

The present invention relates to atomic layer etching (ALE) processes for semiconductor manufacturing, with particular application to high-aspect-ratio (HAR) structures in devices such as 3D NAND, DRAM, and logic circuits. More specifically, the invention pertains to an ALE system and method incorporating rapid in situ liner deposition to enhance etch profile control and reduce sidewall bowing in HAR structures during cyclic etching steps.

### BACKGROUND OF THE INVENTION

The ongoing miniaturization of semiconductor devices has intensified the demand for high-precision etching processes, especially for fabricating structures with high aspect ratios (HAR), such as channel holes in 3D NAND, capacitors in DRAM, and vertical transistor structures like FinFETs in logic devices. HAR structures present significant challenges in plasma etching, primarily due to the difficulty of achieving uniform material removal at certain depths without distorting the desired profile. Conventional ALE processes, which alternate between surface modification and sputtering steps, offer precise, atomic-scale control over material removal. However, these processes often encounter profile deviation and sidewall bowing in HAR applications, affecting the structural integrity and performance of the final devices.

To address these challenges, an in situ liner deposition step may be added at selected intervals of the ALE cycles to protect the sidewalls of HAR structures, thereby preserving the desired etch profile throughout the ALE process. However, the addition of such a step typically introduces considerable overhead in terms of processing time and complexity, as conventional systems may require precursor materials to be delivered from external sources, resulting in extended transition times and potential delays.

Additionally, existing ALE systems generally lack efficient mechanisms for storing and rapidly delivering liner deposition precursors to the process chamber. The time required to introduce these precursors can increase cycle times and impact process throughput. As device architectures continue to evolve and scale, the need for a more efficient, integrated approach to precursor delivery and liner deposition within the ALE process has become critical.

The present invention addresses these limitations by introducing a pressurized precursor buffer, integrated directly within the ALE process system, that enables rapid in situ liner deposition with precise control over precursor delivery. This approach maintains sidewall integrity, enhances etch uniformity in HAR structures, and improves the reliability and efficiency of ALE processes in advanced semiconductor manufacturing.

### SUMMARY

In some embodiments, the invention provides an ALE process system configured to improve profile control and protect sidewalls in HAR structures, such as channel holes in 3D NAND devices, capacitors in DRAM devices, and fins, gates, and source/drain recessed structures prepared for epitaxial layer growth. The system includes a pressurized precursor buffer that enables rapid, delivery of liner deposition precursors directly into the process chamber. In some implementations, the precursor buffer is integrated with a valve system and a time estimator that coordinates the duration of precursor release based on measured precursor's pressure stored in the pressurized buffer and a process recipe.

In some embodiments, the ALE process includes a sequence of conventional ALE cycles, comprising surface modification (step A) and sputtering steps (step B), followed by an additional liner deposition step, referred to as step C. Step C may be introduced after a predetermined number of ALE cycles and can be conducted at selected intervals of the ALE cycles. The pressurized precursor buffer can store precursor under pressure, enabling efficient delivery during step C without requiring long external precursor supply lines, thus reducing transition time and minimizing process overhead.

In certain implementations, the pressurized precursor buffer includes a pressure sensor to monitor internal pressure. This pressure information is used by the system controller to calculate and adjust the duration of precursor release, ensuring consistent and controlled liner thickness and profile. The system controller may include a time estimator, which is a software routine that uses a process recipe and real-time pressure data to determine the optimal release duration for the precursor, enhancing deposition consistency.

In some embodiments, a gas/precursor distribution unit within the process chamber delivers the precursor along with an inert carrier gas, such as argon, which is also used during the sputtering step of the ALE cycle. This design allows the inert gas flow to remain uninterrupted between etching and liner deposition steps, maintaining plasma conditions during transitions and enabling smooth integration of the liner deposition step with minimal disruption to the ALE process. Plasma conditions may be adjusted to suit the liner deposition process.

The liner may include various materials, including but not limited to metal, metal oxide, metal nitride, carbon, carbide, and metal-doped carbon or carbide. The liner may be deposited using a plasma-enhanced chemical vapor deposition (PECVD) process, with step coverage adjustable by changing deposition conditions to clear the etching front from liner deposition. Alternatively, the liner may be deposited using an atomic layer deposition (ALD) process, followed by a punch-through ALE step to remove the liner on the etching front.

In some embodiments, the precursor buffer enables liner deposition to be performed at intervals within the ALE cycles, maintaining sidewall integrity throughout the ALE process. After the ALE step, the liner may either be consumed or removed to initiate subsequent ALE cycles.

The present invention thereby provides an ALE system and method that integrates rapid in situ liner deposition, improving profile control and reducing process time. This approach enhances the precision and efficiency of ALE processing in advanced semiconductor applications, especially where HAR structure fidelity is critical.

### BRIEF DESCRIPTIONS OF THE DRAWINGS

To provide enhanced clarity, the following description references the accompanying drawings:

FIG. 1 illustrates an exemplary process system for an ALE process with rapid in situ liner deposition.

FIG. 2 shows a schematic diagram of the pressurized precursor buffer.

FIG. 3 depicts an exemplary sequence of ALE cycles, including surface modification and sputtering steps, assisted by liner deposition step for forming HAR structures.

FIG. 4 presents a flowchart of the ALE process, assisted with rapid liner deposition steps.

FIG. 5 shows a schematic diagram of the ALE process applied to ONON etching for 3D NAND channels, with rapid liner deposition to reduce bowing of the profile.

### DETAILED DESCRIPTION

To ensure a comprehensive understanding, this section delves into detailed embodiments of the present invention. Although specific details are provided for clarity, modifications and variations aligned with the claims are considered appropriate. Conventional methods and components are highlighted to emphasize the unique features of the invention.

### Definitions

Atomic Layer Etching (ALE): An etching technique that removes atomic layers from a material's surface through cyclic processing steps. ALE typically alternates between a surface modification step (step A) and a sputtering step (step B) to achieve controlled material removal at the atomic level.

High-Aspect-Ratio (HAR) Structures: Structures with a high height-to-width ratio, such as channel holes in 3D NAND, capacitors in DRAM, and gates in logic devices, which pose challenges in etching due to the difficulty for ions and reactive species to uniformly reach deep into narrow channels.

Profile Bowing: The unintended curvature of sidewalls in high-aspect-ratio (HAR) structures during etching, primarily caused by the angular distribution of ions. This effect results in a bow-like shape, impacting critical dimensions and structural integrity in semiconductor devices.

Pressurized Precursor Buffer: A storage unit designed to hold precursor gases or liquids under pressure, used for liner deposition. This buffer is equipped with an inlet, outlet, and pressure sensor to monitor and manage precursor release into the process chamber, working in coordination with the system controller.

System Controller: A central processing unit that manages and coordinates operations of the ALE system, including timing of precursor release, adjusting the vacuum valve, and regulating other process parameters.

Time Estimator: A software routine within the system controller designed to calculate the optimal duration for precursor release based on the ALE process recipe and real-time pressure data from the precursor buffer, ensuring consistent and controlled liner deposition.

Process Chamber: The primary enclosure where the substrate is processed, maintaining a vacuum environment necessary for plasma-based ALE. It is typically constructed from plasma-resistant materials to prevent damage during processing.

Plasma Source: A device that generates plasma within the process chamber, often through inductively coupled plasma (ICP) or transformer coupled plasma (TCP) methods. This source is powered by an RF generator to produce the ionized gas used in etching or deposition.

Gas/Precursor Distribution Unit: A component responsible for delivering process gases or precursors into the process chamber. It may function as an injector or showerhead to distribute gases uniformly across the substrate.

Liner Deposition Step (Step C): An additional step in the ALE cycle introduced to deposit a protective liner on the sidewalls of HAR structures, preserving the etch profile and preventing damage during subsequent etching cycles. This step is performed in situ and can involve PECVD or ALD methods.

Proportional-Integral-Derivative (PID) Control: A feedback mechanism used within the system controller to regulate chamber pressure by adjusting the vacuum valve. PID control stabilizes process conditions for consistent ALE results.

Oxide-Nitride-Oxide-Nitride (ONON) Stack: A multilayer structure used in 3D NAND devices, where oxide and nitride layers alternate. It requires precise etching to form channel holes and is commonly used as a HAR structure example.

Precursor: A reactive gas or liquid stored in the pressurized precursor buffer and introduced into the process chamber for liner deposition. It may be delivered with an inert carrier gas and is used to form a protective liner layer within HAR structures.

Movable Part of the Vacuum Valve: An adjustable component of the vacuum valve that controls gas conductance in the process chamber. Its position is regulated by the PID control to maintain stable chamber pressure, particularly during transitions between process steps.

Chuck: A component that holds and secures the substrate within the process chamber during processing. The chuck may be an electrostatic or vacuum chuck, providing bias control to accelerate ions for the ALE process.

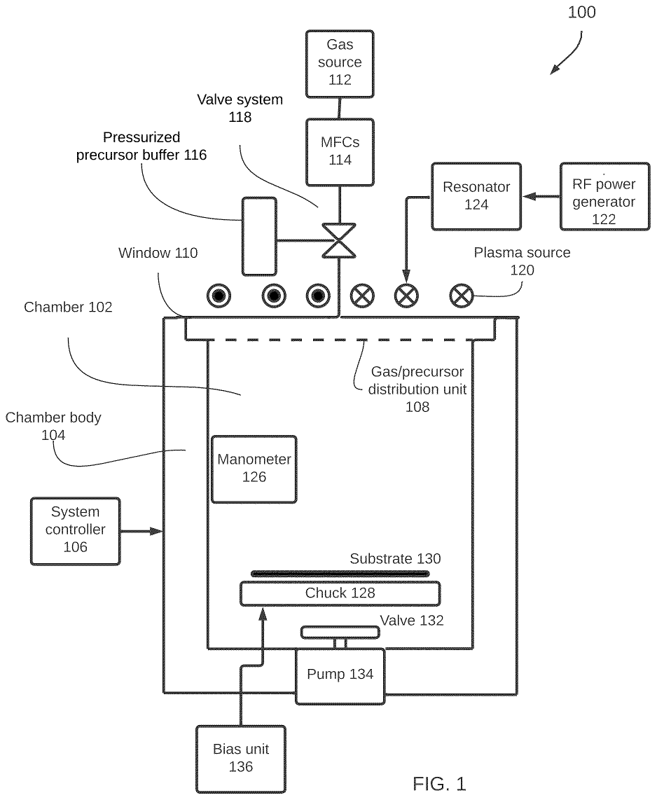

FIG. 1 illustrates an exemplary atomic layer etching (ALE) process system, designated as system 100. This system comprises a process chamber 102, enclosed by a chamber structure 104, with operations coordinated by a system controller 106. Chamber 102 maintains a vacuum environment conducive to plasma processing, and chamber structure 104, constructed from materials such as aluminum or quartz, may feature an anodized or yttrium oxide-coated interior to resist plasma damage.

An exemplary plasma source 120 is positioned above chamber structure 104, separated by a hermetically sealed window 110, which may be constructed from materials such as quartz or ceramics. The window's interior can also be coated with a plasma-resistant material, like yttrium oxide. Plasma source 120 may be configured as an inductively coupled plasma (ICP) or transformer coupled plasma (TCP) source, with configurations like cylindrical or conical multiple-turn coils, and coil turns may vary with more than one coil used.

The plasma source 120 is powered by an RF power generator 122, connected via a resonator 124. Generator 122 can supply RF power at single or multiple frequencies (e.g., 100 kHz, 200 kHz, 2 MHz, 13.56 MHz, 27 MHz, and 60 MHz) with power levels ranging from 50 to 5000 watts. Resonator 124 ensures impedance matching between generator 122 and the plasma load in chamber 102.

A gas/precursor distribution unit 108, connected to a gas source 112 via mass flow controllers (MFCs) 114, delivers process gases to chamber 102 for the ALE process. Valve system 118 controls the flow between MFC 114 and gas/precursor distribution unit 108, which may include one or more valves, configured as two-way or three-way valves.

The ALE process typically includes a surface modification step (step A), followed by a sputtering step (step B), and these steps are performed cyclically. For example, in silicon ALE processing, step A uses a reactive gas, such as chlorine, while step B uses an inert gas like argon. Purging gases from gas source 112 may also be delivered to clear chamber 102 during transitions between process gases.

For HAR etching, deviations from the desired straight profile can occur due to angular distribution of ions. To address this, a liner deposition step, referred to as step C, is introduced to protect sidewalls of HAR structures and preserve the intended etch profile. Step C may be conducted in an external deposition chamber or in situ within chamber 102. Since liner deposition introduces additional processing time and cost, it is essential to minimize overhead while improving profile quality.

The invention introduces a pressurized precursor buffer 116 for storing the precursor used in liner deposition. Buffer 116 is coupled to valve system 118, and system controller 106 regulates the precursor discharge duration from buffer 116, controlling the deposited liner's thickness. The precursor in buffer 116 may be a gas or a liquid, or a mixture of both. In one implementation, a liquid precursor mixed with a carrier gas is stored in buffer 116, and upon release, it vaporizes and is injected into chamber 102 with the carrier gas. In another implementation, the carrier gas is drawn from gas source 112 to transport the vaporized precursor into chamber 102. In yet another implementation, the precursor is stored in gaseous form under pressure in buffer 116.

In a further implementation, the inert gas used during the sputtering step also serves as the carrier gas for the liner deposition precursor, allowing the precursor to be released without switching off the plasma used in the sputtering step. In this setup, the inert gas plasma from the sputtering step is maintained as the precursor is introduced, enabling liner deposition within the existing plasma environment. Power supplied to plasma source 120 and operating conditions for a bias unit 136 coupled to the chuck 128 may vary between sputtering and liner deposition steps to optimize process conditions.

The described ALE process can be utilized to create various HAR structures, including channel holes etched through an oxide-nitride-oxide-nitride (ONON) stack in 3D NAND fabrication, where fluorine-containing gases may be used for step A, and an inert gas may be used for step B. Other HAR applications include holes for storage capacitors in DRAM devices and fin, gate, and source/drain recessed structures for epitaxial layer growth.

The MFCs 114 regulate gas flow before delivery to gas/precursor distribution unit 108, which may act as an injector or showerhead. Window 110 may also be integrated with gas/precursor distribution unit 108, functioning as a showerhead and sealing chamber 102. Chamber pressure is monitored by a manometer 126, while a pump 134 (such as a turbo molecular pump) removes unused gases and byproducts through an exhaust line to an external exhaust system (not shown in FIG. 1).

A vacuum valve 132 controls gas conductance in coordination with pump 134. A valve controller, using a proportional-integral-derivative (PID) control, adjusts the position of the movable part of valve 132 to maintain steady-state chamber pressure as monitored by system controller 106.

Chamber 102 also includes a chuck 128 that supports a substrate 130. Chuck 128 may be an electrostatic or vacuum chuck, and its biasing is critical for the ALE process. It is coupled to a bias unit 136, which may include an additional RF power generator, a tailored waveform generator, or both. Bias unit 136 applies a bias voltage to substrate 130, accelerating ions in the plasma to optimize ALE conditions.

FIG. 1 depicts a single pressurized buffer. However, the number of buffers may exceed one. In some liner deposition processes, multiple precursors are used and may need to be stored in separate buffers for safety reasons.

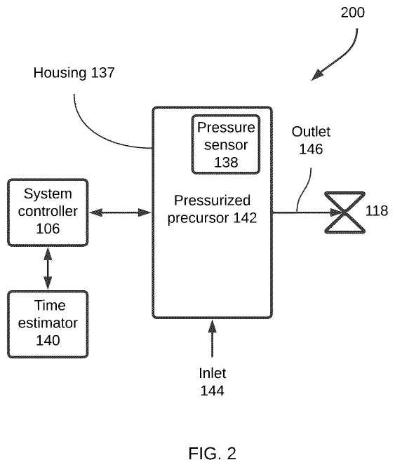

FIG. 2 illustrates a schematic diagram of an exemplary pressurized precursor buffer, designated as 200. Buffer 200 comprises a housing 137 and a pressure sensor 138. The pressurized precursor 142 is stored within housing 137, and the pressure of precursor 142 is monitored by pressure sensor 138 at a predetermined frequency. Housing 137 includes an inlet 144 and an outlet 146, with outlet 146 connected to valve system 118. System controller 106 manages the operations of buffer 200 and is coupled to a time estimator 140, a software routine that calculates the precursor release duration based on the process recipe and measured precursor pressure. The time estimator 140 may include models, analytical formula, lookup tables, and neural networks.

The stored precursor may be in gas, liquid, or a combination of forms. Precursor materials used to deposit the liner may be selected from a group including metal, metal oxide, metal nitride, carbon, carbide, and metal-doped carbon or carbide layers.

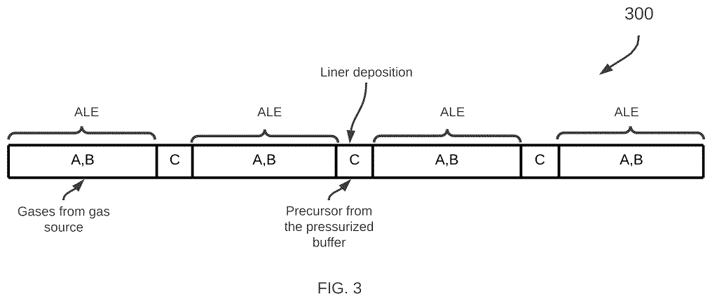

FIG. 3 depicts a schematic diagram of the ALE process sequence 300. The ALE process includes conventional cycles of steps A and B, followed by a liner deposition step, referred to as step C. Step C can be interleaved into cycles of steps A and B as needed to maintain sidewall integrity in HAR structures. Steps A and B utilize process gases from gas source 112, while step C draws precursor from pressurized buffer 116. For a liquid precursor, the carrier gas can either be stored in a mixed form within buffer 116 or supplied separately from gas source 112.

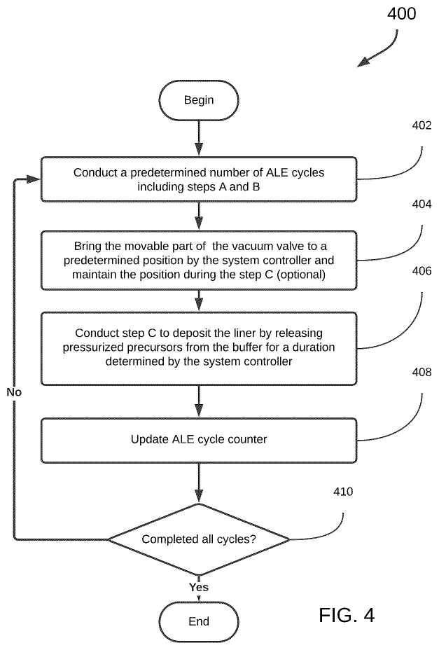

FIG. 4 presents a flowchart of the ALE process 400, illustrating the sequence with rapid liner deposition steps. Process 400 begins with step 402, where a predetermined number of ALE cycles, including steps A and B, are performed. In an optional step 404, to accelerate the transition to liner deposition step C, the movable part of vacuum valve 132 is adjusted to a predetermined position under the control of system controller 106. This position may be defined during a setup phase and stored in a memory unit within system controller 106, remaining fixed during liner deposition step C to maintain optimal conditions.

In step 406, the precursor is released from pressurized precursor buffer 116, with the release duration precisely controlled by system controller 106 in conjunction with time estimator 140. Step C is then executed. In step 408, the ALE cycle counter is updated, and in step 410, system controller 106 checks if the ALE process is complete. If the result is positive, the process concludes. Otherwise, ALE cycles including step C are repeated.

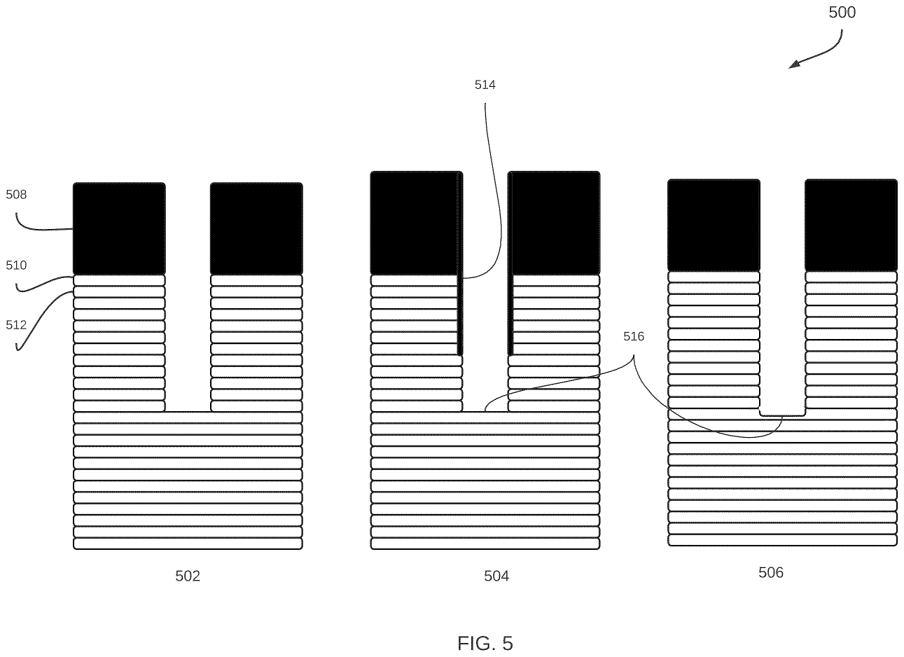

FIG. 5 illustrates an example application of the ALE process for etching an ONON stack to form channel holes in 3D NAND devices. The structure undergoing ALE steps A and B is labeled 502. A hard mask, such as a carbon layer, is denoted as 508, while oxide and nitride layers are labeled as 510 and 512, respectively. In 504, a protective liner 514 is deposited. In one implementation, liner 514 is deposited via a PECVD process. The PECVD-deposited liner has a specific step coverage factor and may not reach the etching front 516, as shown in 504. Additional ALE cycles are conducted in 506 to advance the etching front, with liner 514 protecting the sidewalls of the structure during processing. After the ALE cycles, the liner is removed to resume new cycles of ALE steps A and B, followed by step C as needed.

In an alternative implementation, the liner is deposited using an ALD process, followed by a punch-through step using the ALE process to remove the liner material at the etching front, maintaining a clean etching front for subsequent ALE process.

1. A process system for ALE, comprising:
a process chamber configured to receive a substrate and maintain a vacuum environment for plasma-based processing;
a plasma source coupled to the process chamber and configured to generate plasma within the chamber;
a gas/precursor distribution unit connected to a gas source and configured to deliver process gases to the process chamber for an ALE process;
a pressurized precursor buffer positioned proximate to the gas/precursor distribution unit and configured to store and release a precursor, the pressurized precursor buffer comprising:
a housing with an inlet and an outlet,
a pressure sensor to monitor internal pressure of the precursor, and
wherein the buffer is connected to a valve system to control precursor flow from the buffer into the process chamber; and
a system controller connected to the pressurized precursor buffer, the system controller being configured to:
execute a sequence of ALE cycles comprising a surface modification step and a sputtering step,
initiate a rapid liner deposition step by releasing the precursor from the pressurized precursor buffer after a predetermined number of ALE cycles.

2. The system of claim 1, wherein the system controller is configured to maintain a movable part of a vacuum valve during the liner deposition step to reduce the time required to establish steady precursor pressure in the process chamber.

3. The system of claim 1, wherein the pressurized precursor buffer is configured to store a liquid precursor.

4. The system of claim 3, wherein the liquid precursor is stored in combination with a carry gas.

5. The system of claim 3, wherein the liquid precursor is vaporized while being released from the buffer, the liquid precursor is delivered into the process chamber with a carry gas drawn from the gas source.

6. The system of claim 5, wherein the carry gas is identical to the gas used for the sputtering step.

7. The system of claim 1, wherein the pressurized precursor buffer is configured to store a gaseous precursor.

8. The system of claim 1, wherein the precursor is released from the buffer into the process chamber while the plasma in the process chamber is maintained from the previous sputtering step of the ALE cycle, wherein the liner deposition step leverages the plasma.

9. The system of claim 8, wherein the plasma is maintained with altered operating conditions from the sputtering step, including different powers from RF generators and a different bias from a bias unit coupled to a chuck supporting the substrate.

10. The system of claim 1, wherein the pressure sensor in the pressurized precursor buffer is configured to transmit real-time pressure data to the system controller for adaptive adjustment of the precursor release duration based on a process recipe.

11. The system of claim 1, wherein the liner is selected from a group consisting of metal, metal oxide, metal nitride, carbon, carbide, or metal-doped carbon or carbide layers.

12. The system of claim 1, wherein the ALE is utilized for forming HAR structures comprising an ONON stack configured to form channel holes for 3D NAND devices.

13. The system of claim 1, wherein the ALE is utilized for forming HAR structures comprising holes used to form DRAM capacitors.

14. The system of claim 1, wherein the ALE is utilized for forming HAR structures comprising one or more stacks including silicon, germanium, metal, nitride, oxide, and carbon.

15. The system of claim 1, wherein the liner is deposited using an ALD process, followed by a punch-through etching step performed by the ALE process to remove deposited materials on the etching front.

16. A method for ALE of HAR structures in a substrate, comprising:
performing a sequence of ALE cycles within a process chamber, each ALE cycle including a surface modification step and a sputtering step;
initiating, after a predetermined number of ALE cycles, a liner deposition step by releasing a precursor from a pressurized precursor buffer positioned proximate to a gas/precursor distribution unit within the process chamber; and
controlling the duration of the precursor release based on real-time pressure data from a pressure sensor within the pressurized precursor buffer to achieve a controlled liner thickness.

17. The method of claim 16, further comprising dynamically adjusting the precursor release duration based on a process recipe and real-time pressure data from the pressure sensor in the pressurized precursor buffer.

18. The method of claim 16, wherein the liner is selected from a group consisting of metal, metal oxide, metal nitride, carbon, carbide, or metal-doped carbon or carbide layers, and the liner deposition forms a protective layer on the sidewalls of the HAR structures.

19. The method of claim 16, wherein the liner is deposited using an atomic ALD process, followed by a punch-through etching step performed by the ALE process to remove deposited materials on the etching front.

20. The method of claim 16, wherein the liner is deposited using a PECVD process, wherein the step coverage of the liner is adjustable by changing deposition conditions.
